(19) United States
(12) Patent Application Publication
(10) Pub. No.: US 2026/0096102 A1
(43) Pub. Date: Apr. 2, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: YEN-CHIEH HUANG, CHANGHUA COUNTY (TW); CHAO-I WU, HSINCHU COUNTY (TW); HUAI-YING HUANG, NEW TAIPEI CITY (TW); YU-MING LIN, HSINCHU CITY (TW)

(21) Appl. No.: 18/902,994

(22) Filed: Oct. 1, 2024

(51) Int. Cl. H10B 51/30; H01L 23/522; H01L 29/423; H01L 29/66; H01L 29/78; H10B 51/10

(52) U.S. Cl. CPC H10B 51/30; H10B 51/10; H10D 30/0415; H10D 30/701; H10D 64/514; H10W 20/42

(57) ABSTRACT

A semiconductor structure is provided. The semiconductor structure includes a substrate, a metallization structure over the substrate, and a memory structure embedded in the metallization structure. The metallization structure includes at least a dielectric layer and at least a conductive line layer. The memory structure is further laterally surrounded by the dielectric layer. The memory structure includes a bottom metal layer, a ferroelectric layer, a floating metal layer, and an insulating layer. The ferroelectric layer is over the bottom metal layer. The floating metal layer is over the ferroelectric layer. The insulating layer is over the floating metal layer. The metallization structure further includes a first conductive via and a second conductive via over the insulating layer and in proximity to two opposite sides of the floating metal layer, respectively. A method of manufacturing a semiconductor structure is also provided.

### BACKGROUND

Many modern-day electronic devices include non-volatile memory. Non-volatile memory is electronic memory that is able to store data in the absence of power. A promising candidate for the next generation of non-volatile memory is ferroelectric random-access memory (FeRAM). FeRAM has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor structure according to some embodiments of the present disclosure.

FIG. 2 illustrates a cross-sectional view of a semiconductor structure according to some embodiments of the present disclosure.

FIG. 3A illustrates a top view of a floating metal layer along the line AA′ in FIG. 2, according to some embodiments of the present disclosure.

FIG. 3B illustrates a top view of a floating metal layer along the line AA′ in FIG. 2, according to some embodiments of the present disclosure.

FIG. 4A illustrates a cross-sectional view of a MFIS portion in a semiconductor structure according to some embodiments of the present disclosure.

FIG. 4B illustrates a cross-sectional view of a MFMIS portion in a semiconductor structure according to some embodiments of the present disclosure.

FIG. 5A illustrates a cross-sectional view of a semiconductor structure according to some embodiments of the present disclosure.

FIG. 5B illustrates a top view of a memory structure enclosed by a dielectric isolating structure according to some embodiments of the present disclosure.

FIG. 5C illustrates a cross-sectional view of a semiconductor structure according to some embodiments of the present disclosure.

FIG. 6A illustrates a top view of a memory structure according to some embodiments of the present disclosure.

FIG. 6B illustrates a top view of a memory structure according to some embodiments of the present disclosure.

FIGS. 7A to 7J illustrate cross-sectional views of a method of manufacturing a semiconductor structure according to some embodiments of the present disclosure.

FIG. 8 illustrates a flow chat of a method for manufacturing a semiconductor structure according to some embodiments of the present disclosure.

FIGS. 9A to 9D illustrate cross-sectional views of a method of manufacturing a semiconductor structure according to some embodiments of the present disclosure.

FIG. 10 illustrates a cross-sectional view of a semiconductor structure according to some embodiments of the present disclosure.

FIG. 11 illustrates a cross-sectional view of a semiconductor structure according to some embodiments of the present disclosure.

FIG. 12 illustrates a cross-sectional view of a semiconductor structure according to some embodiments of the present disclosure.

FIG. 13 illustrates a cross-sectional view of a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

Ferroelectric materials are used in memory structures because of their ability to retain a polarization state even after the applied electric field is removed. This property allows them to store information in a non-volatile manner, making them suitable for use in memory devices. In some comparative embodiments of a memory structure, ferroelectric materials are typically integrated as a thin film between two electrodes. When a voltage is applied across the electrodes, the polarization of the ferroelectric material can be switched between two stable states, representing the 0 and 1 states of digital information. This allows the ferroelectric memory to store data without the need for continuous power supply, making it ideal for applications where power consumption is a concern.

The ferroelectric random-access memory (FeRAM) is an example of high-performance non-volatile memory that includes ferroelectric materials. Essentially, there are two types of FeRAM have been evaluated based on the practical use. One type is made of transistors connected with capacitors, such as 1T1C or chain FeRAM structures. The other is a field-effect transistor and is referred to as the ferroelectric memory field-effect transistor (FeMFET). The FeMFET has potential for technical use as a nondestructive read out (NDRO) and high-density non-volatile memory. The structure of FeMFET is similar to the common metal-oxide semiconductor field-effect transistor (MOSFET), whereas only the gate material in the FeM-FET is a ferroelectric material rather than the usual oxide. With writing at a gate voltage, +V_{w} or −V_{w}, the dipole moments are stored, and the direction of polarization is set in the ferroelectric material. This results in the threshold voltage difference of the two states of the FeMFET and can be identified as two logic states in a memory. However, the direct deposition of the ferroelectric material on a semiconductor substrate (e.g., a silicon substrate) may cause interdiffusion near the interface, which in turn will degrade the device performance. Thus, an insulating buffer layer is inserted between the semiconductor substrate and the ferroelectric material in order to give better interfacial properties. Such device structure is referred to as the metal-ferroelectric-insulator-semiconductor field-effect transistor (MFIS-FET). The MFIS-FET, however, has a small memory window (MW) under the low operation voltages. Therefore, metal-ferroelectric-metal-insulator-semiconductor field-effect transistor (MFMIS-FET) with a floating metal gate sandwiched by the ferroelectric material and an insulating layer has been provided. The main merit of this device is that the area of a metal-ferroelectric-metal (MFM) capacitor can be changed to be smaller than that of metal-insulator-semiconductor (MIS). This would make the capacitance of MIS comparable to that of MFM, such that the voltage drop across the ferroelectric materials can be enhanced. As a result, the applied voltage becomes more efficient in driving the ferroelectric material into the state of saturated polarization. Therefore, the operation voltage for an MFMIS-FET can be lower than MFIS-FET.

To be more detailed in the application aspect, the MFIS-based memory devices (i.e., those with a memory structure including the MFIS-FET) can provide high-speed operation because their gate control ability is relatively better than that of the MFMIS-based memory devices (i.e., those with a memory structure including the MFMIS-FET). However, as aforementioned, the memory window of MFIS-based memory devices is relatively low. The memory window control of MFMIS-based memory devices is good because they have a larger 2Pr, but the channel control ability of MFMIS-based memory devices is relatively limited due to the effective oxide thickness (EOT), while a high EOT would reduce the channel control ability. In other words, the limitations of each memory device should be considered in its application, and it is worth considering whether memory devices can be enhanced to have advantages from diverse types of memory structures.

Therefore, some embodiments of the present disclosure provide a semiconductor structure that includes an integrated memory structure having both the features of the MFIS structure and the MFMIS structure, and such integrated memory structure may have an enhanced memory window, 2Pr control ability compared to an ordinary MFIS-based memory device, and keep a good gate control ability. Moreover, the integrated memory structure may provide more tuning knobs to fine-tune device characteristics. For example, the memory window, the Iₒₙ (which is relatively low in MFMIS-based memory devices and relatively high in MFIS-based memory devices), the I_{on_PRG} (i.e., the on-current of programing), the I_{on_ERS} (i.e., the on-current of erasing), the endurance of the devices, the data retention, etc.

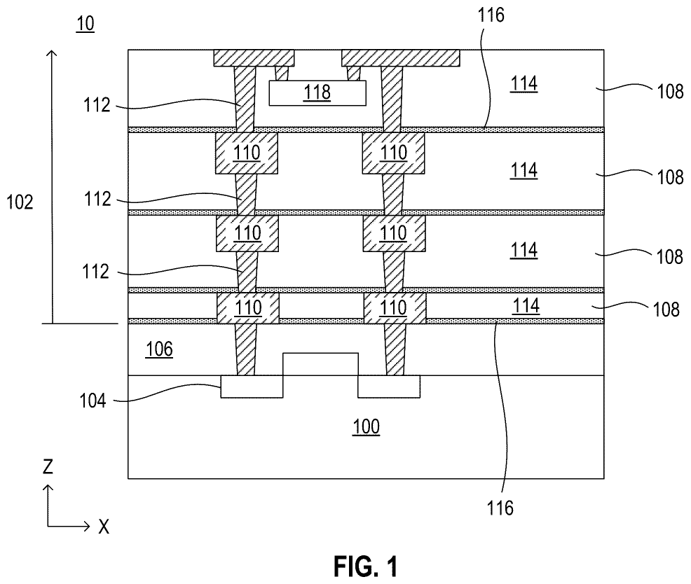

FIG. 1 is a diagram of an example semiconductor structure 10 describe herein. Referring to FIG. 1, in some embodiments, the semiconductor structure 10 includes a substrate 100 and a metallization structure 102 over the substrate 100. In some embodiments, a front-end-of-line (FEOL) structure 104 and/or a middle-end-of-line (MEOL) structure 106 can be formed over the substrate 100 subsequently prior to the forming of the metallization structure 102.

In some embodiments, the substrate 100 is a silicon substrate. In some embodiments, the substrate 100 may be made by some other semiconductor material such as germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, and the like, may also be used. Additionally, the substrate 100 may include a silicon-on-insulator (SOI) substrate. Generally, an SOI substrate includes a layer of semiconductor material such as epitaxial silicon, germanium, silicon germanium, SOI, silicon germanium on insulator (SGOI), or combinations thereof. The substrate 100 may be doped with a p-type dopant such as boron, boron fluorine, aluminum, gallium, or the like. The substrate may alternatively be doped with an n-type dopant such as phosphorus, arsenic, antimony, or the like.

The FEOL structure 104 is the one of the portions of IC fabrication where the components such as transistors are formed in the substrate 100. The FEOL structure 104 may include various kinds of individual devices. In some embodiments, the individual devices may include various microelectronic devices, for example, metal-oxide-semiconductor field effect transistor (MOSFET), planar transistor, fin field effect transistor (finFET), gate all around (GAA) transistor, large scale integration (LSI) system, complementary metal-oxide-semiconductor (CMOS) imaging sensor (CIS), micro-electro-mechanical system (MEMS), pixel sensor, capacitor, resistor, inductor, photodetector, transceiver, transmitter, receiver, optical circuit, and/or other active device or passive device. The individual devices may be electrically connected to a conductive region of the substrate 100.

The definitions of what is considered the MEOL structure 106 may vary, whereas in some embodiments of the present disclosure, the MEOL structure is referred to the region that formed over a surface of the substrate 100 and below a first metal layer (M1) of the metallization structure 102. In some embodiments, the material of the MEOL structure 106 includes dielectric material, which may be referred to as a pre-metal dielectric (PMD). In other words, the MEOL structure 106 can be distinguished from the substrate 100 there below and the metallization structure 102 thereon by a number of process parameters, such as the choice of the fundamental material, or the choice of the metal used. For instance, the material of the MEOL structure 106 can include low-k dielectric material with a small dielectric constant relative to silicon dioxide, and thus can be distinguished from the material of the substrate 100; likewise, the metal usually used in the MEOL structure 106 for electrical connect is tungsten (W), while the metals usually used in the metallization structure 102 is copper (Cu). These are several exemplary approaches to distinguish the stacked structures over the substrate 100.

The metallization structure 102 in the semiconductor structure 10 may refer to a BEOL structure under an aspect that interconnect layers formed after the individual devices have been fabricated. In some embodiments, metallization structure 102 includes a plurality of conductive line layers 108. Each of the conductive line layer 108 may have a conductive line portion 110 and a conductive via portion 112 in contact with the conductive line portion. In some embodiments, the conductive line layer 108 that is closest to the MEOL structure 106 may be referred to as a first metal layer, while the conductive line portion 110 and the conductive via portion 112 can be briefly called M1 and V1, respectively. Likewise, within the conductive line layers further stacked over the first metal layer, the conductive line portions and the conductive via portions thereof can be briefly called M2, M3, M4, . . . Mx and V2, V3, V4, . . . Vx, respectively. The material of the conductive line layer may one or more electrically conductive materials such as tungsten (W), cobalt (Co), ruthenium (Ru), titanium (Ti), aluminum (Al), copper (Cu), gold (Au), and/or combination thereof.

In addition, in a typical BEOL structure, the metallic material in the metal line portion 110 and the conductive via portion 112 is surrounded by dielectric materials. As illustrated in FIG. 1, in some embodiments, the metallization structure 102 in the semiconductor structure 10 can include a plurality of inter-metal dielectric (IMDs) 114. In some embodiments, the IMD 114 includes oxide (e.g., a silicon oxide (SiOₓ) and/or another oxide material), undoped silicate glass (USG), a boron-containing silicate glass (BSG), fluorine-containing silicate glass (FSG), tetraethyl orthosilicate (TEOS), hydrogen silsesquioxane (HSQ), and/or another suitable dielectric material. In some embodiments, the IMD 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

In some embodiments, the metallization structure 102 in the semiconductor structure 10 can include a plurality of etch stop layers (ESL) 116 below the plurality of IMDs 114. The ESLs 116 can each include silicon nitride (SiₓN_{y}), silicon carbide (SiC), silicon oxynitride (SiON), and/or another suitable dielectric material. In some embodiments, the IMD 114 and ESL 118 include different dielectric materials to provide etch selectivity to enable various structures to be formed in the metallization structure 102.

In some embodiments, a memory structure 118 is embedded in the metallization structure 102. In some embodiments, the memory structure 118 is embedded in the dielectric material of the metallization structure 102. For example, the memory structure 118 can be laterally surrounded by one of the IMD 114 and therefore between two vertically adjacent conductive line layers 108. In some embodiments, the memory structure 118 is spaced from the ESL 116 there below by a portion of the IMD 114. In some embodiments, the height of the memory structure 118 is no greater than the thickness of the IMD 114 where the memory structure 118 is embedded therein.

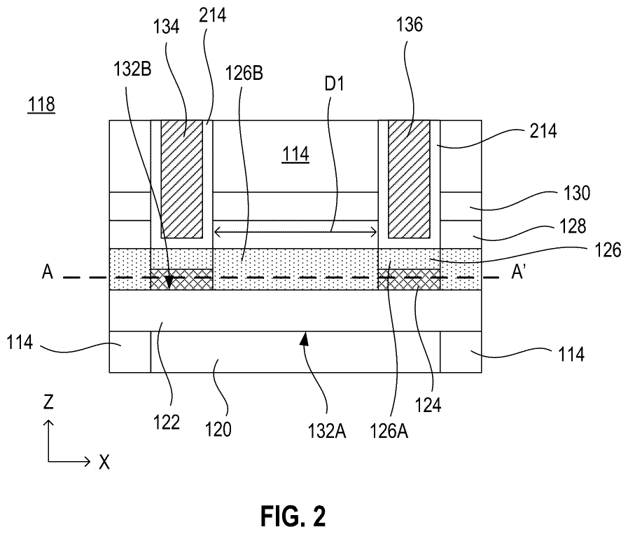

The memory structure 118 in the present disclosure is an integrated memory structure that having the structure features of the MFIS structure and the MFMIS structure. Referring to FIG. 2, which illustrates the structure detail of the memory structure 118 that is embedded in the metallization structure previously shown in FIG. 1. In some embodiments, the memory structure 118 can include a bottom metal layer 120, a ferroelectric layer 122 over the bottom metal layer 120, a floating metal layer 124 over the ferroelectric layer 122, and an insulating layer 126 over the floating metal layer 124.

In some embodiments, the bottom metal layer 120 may be implemented as the metal gate that used to control the flow of electrons within the memory structure (e.g., the memory cell). The bottom metal layer 120 can be electrically coupled to a voltage source V_{G}, which allows for the manipulation of the charge stored in the memory structure. In some embodiments, the material of the bottom metal layer 120 can include tungsten (W), titanium nitride (TiN), copper (Cu), aluminum (Al), gold (Au), platinum (Pt), etc. In some embodiments, the thickness of the bottom metal layer 120 is in a range from about 50 nm to about 10,000 nm.

In some embodiments, the ferroelectric layer 122 over the bottom metal layer 120 is implemented as the storage element in the memory structure, it may exhibit a spontaneous polarization that can be switched between two stable states, representing the 0 and 1 states of the memory structure. Thus, it allows for non-volatile data storage with low power consumption and high endurance. In some embodiments, the material of the ferroelectric layer 122 can include HfO₂, Zr-doped HfO₂, Al-doped HfO₂, PbTiO₃, SrTiO₃, etc. In some embodiments, the thickness of the ferroelectric layer 122 is in a range from about 1 nm to about 1,000 nm.

In some embodiments, the floating metal layer 124 over the ferroelectric layer 122 is implemented to store and manipulate charge, allowing the memory structure to retain data even when the power is turned off. That is, when a voltage is applied to the floating metal layer 122, it creates an electric field that can attract or repel charge carriers in the semiconductor material (e.g., a channel material over the insulating layer 126, which will be described later), and thus effectively changing the state of the memory structure. In some embodiments, the material of the floating metal layer 124 can include tungsten (W), titanium nitride (TiN), copper (Cu), aluminum (Al), gold (Au), platinum (Pt), etc. In some embodiments, the thickness of the floating metal layer 124 is in a range from about 0.1 nm to about 50 nm.

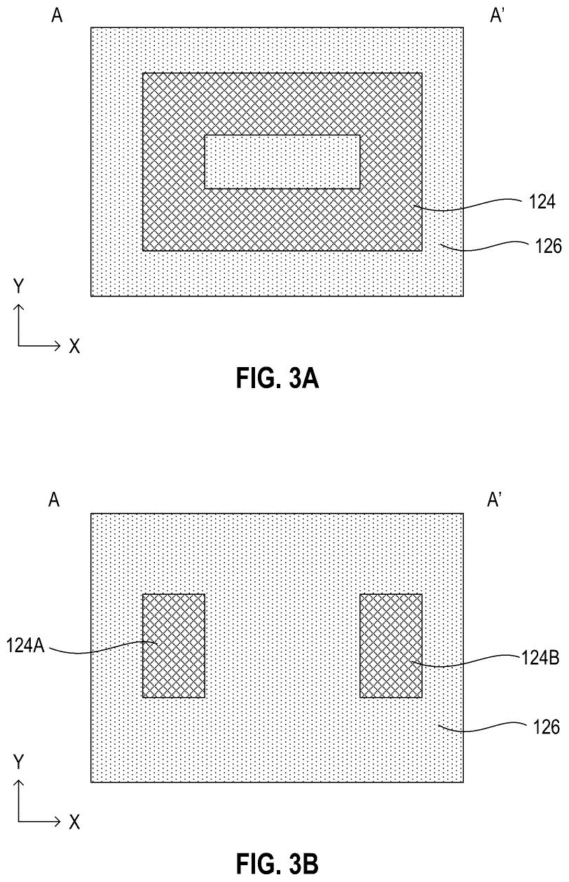

In some embodiments, the floating metal layer 124 in a single memory structure (e.g., one memory cell) is not a thin film structure that completely covers the underlying layer. Referring to FIG. 3A, in some embodiments, the floating metal layer 124 includes a ring profile from the top view perspective. In some examples, the floating metal layer 124 can substantially include a square frame profile from the top view perspective. Referring to FIG. 3B, in other embodiments, the floating metal layer includes a first portion 124A and a second portion 124B isolated from the first portion 124A. In some examples, each of the first portion 124A and the second portion 124B can include a rectangular or a circular profile from the top view perspective. In some embodiments, within a region or an area of the single memory structure, a center of the floating metal layer 124 having the ring profile from the top view perspective is aligned to a center of the ferroelectric layer 122 (see FIGS. 2, and 3A). In other embodiments, the two separated portions of the floating metal layer 124 are symmetrical to a center of the region/area of the single memory structure (see FIGS. 2, and 3B). In other words, the floating metal layer 124 exposes a portion of the ferroelectric layer 122, where the exposed portion is substantially includes the center of the ferroelectric layer 122.

Referring to FIG. 2, in some embodiments, the insulating layer 126 over the floating metal layer 124 is implemented to separate the ferroelectric layer 122 and the floating metal layer 124 from the semiconductor material to prevent leakage of charge between these layers and the semiconductor material. Furthermore, the insulating layer 126 may also maintain the polarization of the ferroelectric layer 126, and thus may ensure that the stored data remains stable and does not degrade over time. In some embodiments, the material of the insulating layer 126 can include SiO₂, SiNₓ, HfOₓ, AlOₓ, etc. In some embodiments, the thickness of the insulating layer 126 is in a range from about 1 nm to about 50 nm.

In some embodiments, a channel layer 128 is over the insulating layer 126, the channel layer 128 can be implemented to act as a bridge between the ferroelectric material and the metal electrodes in the memory structure. When a voltage is applied to the channel layer 128, it may modulate the conductivity of the channel, allowing for the manipulation of the ferroelectric polarization and the storage of data. In some embodiments, the material of the channel layer 128 can include InP, GaP, GaN, GaSb, GaAs, AlAs, InAs, InSb, AlGaAs, Si, Ge, SiGe, InGaZnO, InO GaZnOₓ, InGaSnOₓ, GaInAs, GaInP, InAlAs, InGaAs, AlInGaP SnOx, etc. In some embodiments, the thickness of the channel layer 128 is in a range from about 1 nm to about 500 nm.

In some embodiments, the channel layer 128 is covered by a cap layer 130. In some embodiments, the material of the cap layer 130 can include AlOₓ, or SiOₓ (x=0 to 2). In some embodiments, the thickness of the cap layer 130 is in a range from about 1 nm to about 500 nm.

In some embodiments, the metallization structure 102 may include a lower interface layer 132A between the bottom metal layer 120 and the ferroelectric layer 122. In some embodiments, the material of the lower interface layer 132A can include TiOₓ, HfOₓ, ZrOₓ, NbOₓ, or CeOₓ (x=0 to 2). In some embodiments, the thickness of the lower interface layer 132A is in a range from about 0.1 nm to about 20 nm. In addition, the metallization structure 102 may further include an upper interface layer 132B between the ferroelectric layer 122 and the floating metal layer 124. In some embodiments, the material of the lower interface layer 132B can include TiOₓ, HfOₓ, ZrOₓ, NbOₓ, or CeOₓ. In some embodiments, the thickness of the upper interface layer 132B is in a range from about 0.1 nm to about 20 nm. In some embodiments, the lower interface layer 132B is also between the ferroelectric layer 122 and the insulating layer 126.

Since the ferroelectric layer 122 is free from completely covering by the floating metal layer 124, in some embodiments, the insulating layer 126 is at least in contact with the top surface of the ferroelectric layer 122 at a center region of the ferroelectric layer 122. In other words, the profiles of the floating metal layer 124 can be used to determine the portion of the ferroelectric layer 122 that exposed to in contact with the insulating layer 126. By using the floating metal layer 124 covering a portion of the ferroelectric layer 122, within the area, which includes the floating metal layer 124 spacing apart the ferroelectric layer 122 and the insulating layer 126, can be referred as a portion of a MFMIS structure. On the other hand, within the area free from having the floating metal layer 124, the insulating layer 126 may be in contact with the ferroelectric layer 122, and such area may be a portion of a MFIS structure.

As aforementioned, the floating metal layer 124 may include the first portion 124A and the second portion 124B from the cross sectional perspective (see FIG. 3B); in some embodiments, these portions of the floating metal layer 124, not matter they are being a continuous thin layer structure (e.g., the embodiment shown in FIG. 3A) or being isolated from each other (e.g., the embodiment shown in FIG. 3B), the floating metal layer 124 can be covered by a first portion 126A of the insulating layer 126 and laterally surrounded by a second portion 126B of the insulating layer 126 (see FIG. 2). In some embodiments, the insulating layer 126 is a continuous thin layer structure wherein the different portions are defined based whether the floating metal layer 124 is projectively located below the insulating layer 126. In some embodiments, the thickness of the floating metal layer 124 is less than the thickness of the second portion 126B of the insulating layer 126.

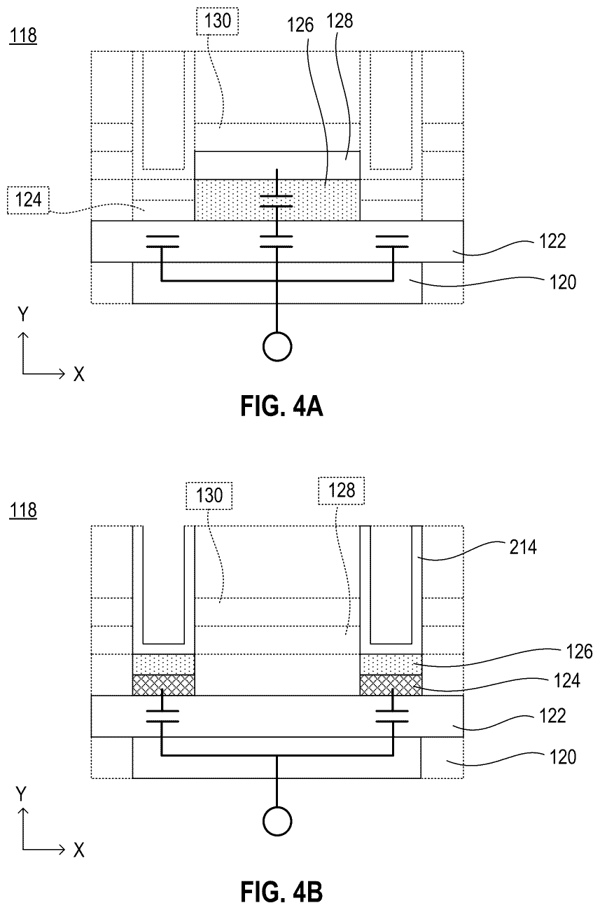

Referring to FIGS. 4A and 4B, which illustrate that different portions of the memory structure 118 can be functioned as a MFIS memory and a MFMIS memory, respectively. In these figures, the dashed lines are used to indicate parts that exist within the memory structure 118 but do not serve functions related to the MFIS memory or the MFMIS memory. For example, the two portions of the floating metal layer 124 in the cross-sectional perspective are substantially included as a part of the MFMIS memory, rather than being considered part of the MFIS memory. On the other hand, as the illustration in FIGS. 4A and 4B, it is clear that the MFIS structure and the MFMIS structure can be integrated in a single memory structure and be functioned based on the requirement of the user, and therefore the advantages of the MFIS memory or the MFMIS memory can be substantially performed in a single memory structure.

Referring to FIG. 2, in some embodiments, the metallization structure 102 further includes a first conductive via 134 and a second conductive via 136 over the insulating layer 126. In some embodiments, the first conductive via 134 and the second conductive via 136 are in proximity to two opposite sides of the floating metal layer 124, respectively. The first conductive via 134 and the second conductive via 136 are configured to electrically coupled to the conductive line layers 108 in the metallization structure 102, and can be implemented as a source/drain contact for the memory structure 118. In some embodiments, a bottom side and a lateral side of each of the first conductive via 134 and the second conductive via 136 are in contact with the material of the channel layer 128 through a conductive metal oxide layer 214 of the first conductive via 134 and the second conductive via 136. In some embodiments, the first conductive via 134 and a second conductive via 136 are projectively over the floating metal layer 124.

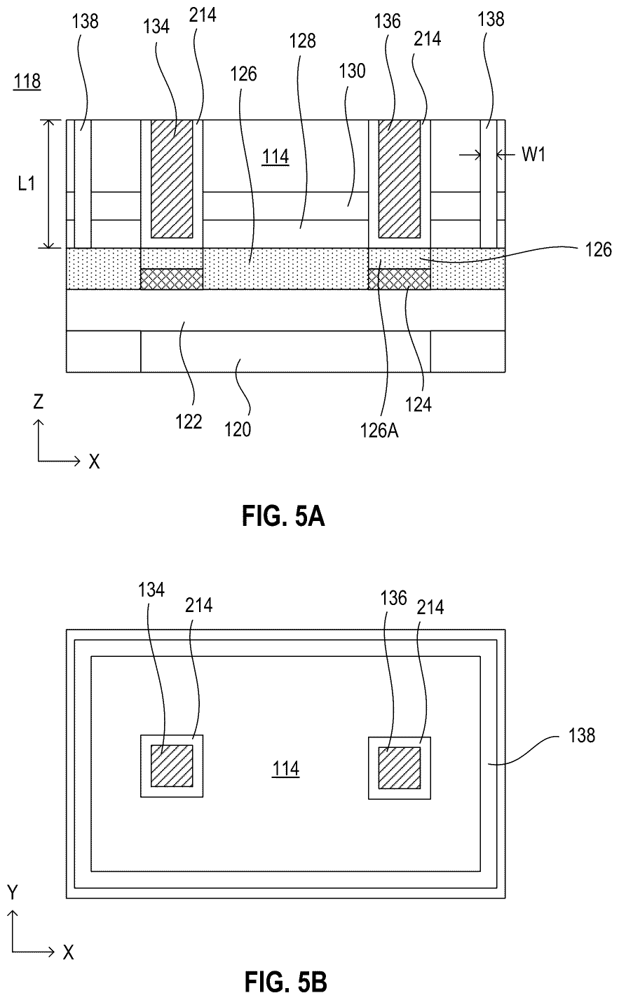

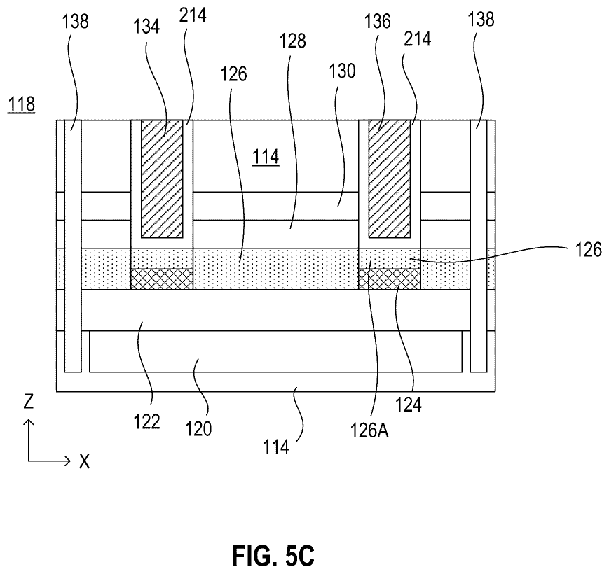

Referring to FIGS. 5A to 5C, in some embodiments, the channel layer 128 is cut off by a dielectric isolating structure 138. For instance, the dielectric isolating structure configured to cut off the channel layer 128 can be a trench type structure filled by a dielectric material and laterally enclosing the memory structure 118. In some embodiments, a bottom of the dielectric isolating structure 138 is substantially leveled to an upper surface of the insulating layer 126 (see FIG. 5A). In some embodiments, the bottom of the dielectric isolating structure 138 is substantially leveled to a bottom surface of the bottom metal layer 120 (see FIG. 5C). In some embodiments, a length L1 of the dielectric isolating structure 138 from a top side leveled to an upper surface of the cap layer 130 to a bottom side is in a range from about 100 nm to about 10,000 nm. In some embodiments, a width W1 of the dielectric isolating structure 138 is in a range from about 10 nm to about 1,000 nm. In some embodiments, the material of the dielectric isolating structure 138 is substantially identical to the material of the IMD 114.

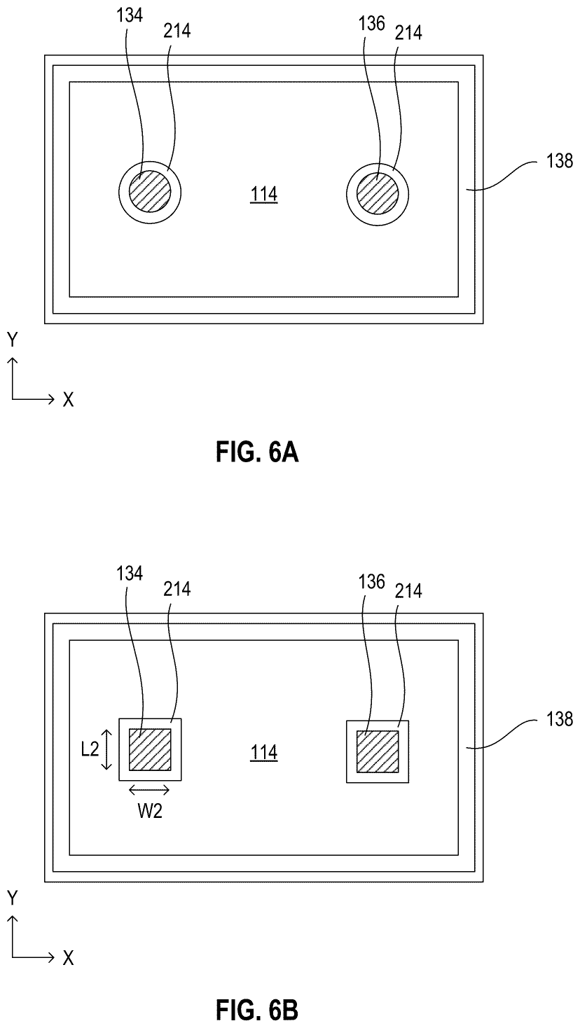

Referring to FIG. 6A, in some embodiments, each of the first conductive via 134 and the second conductive via 136 may have a circular cross-sectional profile. In some embodiments, the first conductive via 134 and the second conductive via 136 with the circular cross-sectional profile may have a diameter in a range from about 10 nm to about 1,000 nm. In other embodiments, referring to FIG. 6B, each of the first conductive via 134 and the second conductive via 136 may have a square cross-sectional profile. In the embodiment that each of the first conductive via 134 and the second conductive via 136 has the square cross-sectional profile, the square cross-sectional profile may have a length L2 in a range from about 10 nm to about 1,000 nm and a width W2 in range from about 10 nm to about 1,000 nm.

In the aspect of the profile of the layers in the memory structure 118, referring to FIG. 2, in some embodiments, a side of the ferroelectric layer 122 is aligned to a side of the insulating layer 126, and the side of the ferroelectric layer 122 is free from aligning to a side of the bottom metal layer 120. For example, the area of the bottom metal layer 120 can be smaller than the ferroelectric layer 122, and therefore the bottom metal layer 120 can be entirely covered by the ferroelectric layer 122. Different from the area difference between the bottom metal layer 120 and the ferroelectric layer 122, in some embodiments, the area of the ferroelectric layer 122 is substantially identical to the area of the insulating layer 126, and therefore the sides of these layers can be vertically aligned.

In some embodiments, the two opposite sides of the floating metal layer 124 are substantially aligned to two opposite sides of the bottom metal layer 120. In some embodiments, the floating metal layer 124, no matter it is a continuous thin layer structure or two isolated structures, the floating metal layer 124 is enclosed by the edges of the ferroelectric layer 122 from the top view perspective, and the floating metal layer 124 may aligned to the metal electrode structure below the ferroelectric layer 122, such as the bottom metal layer 120.

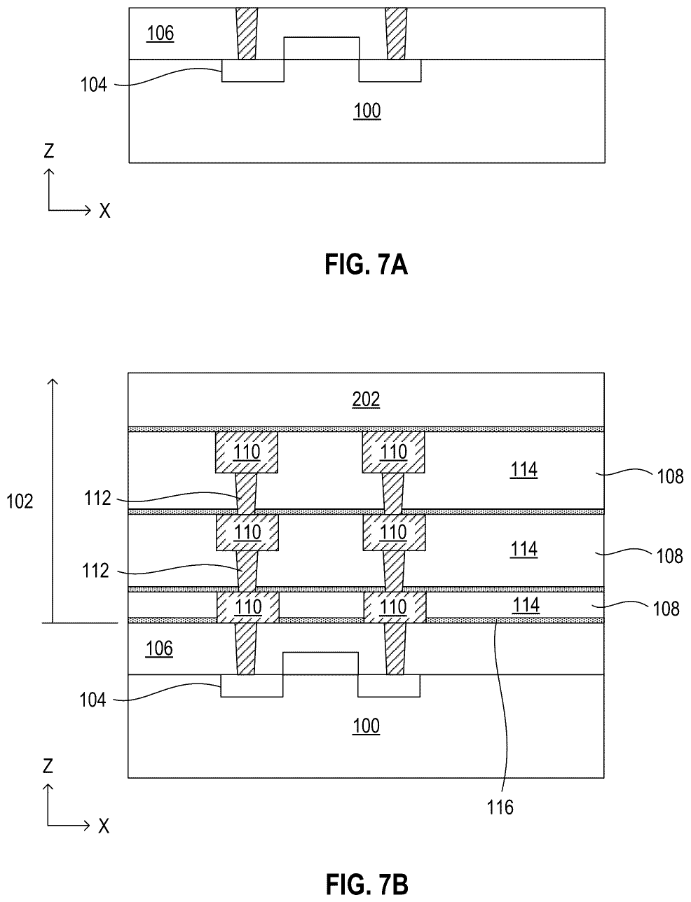

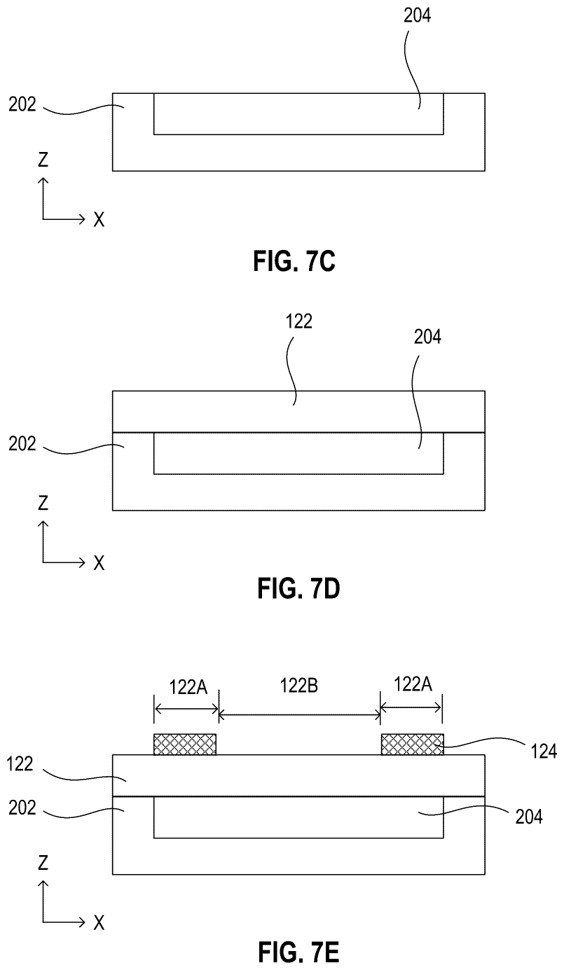

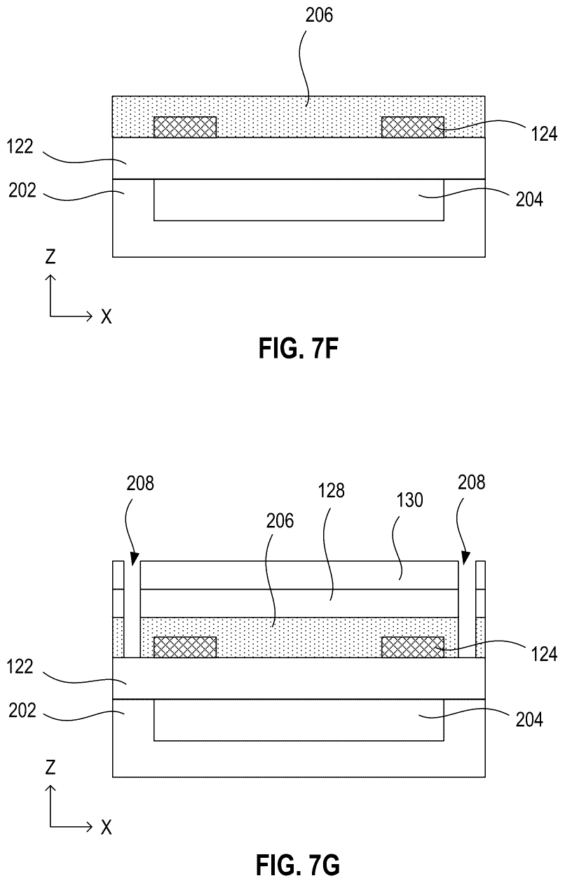

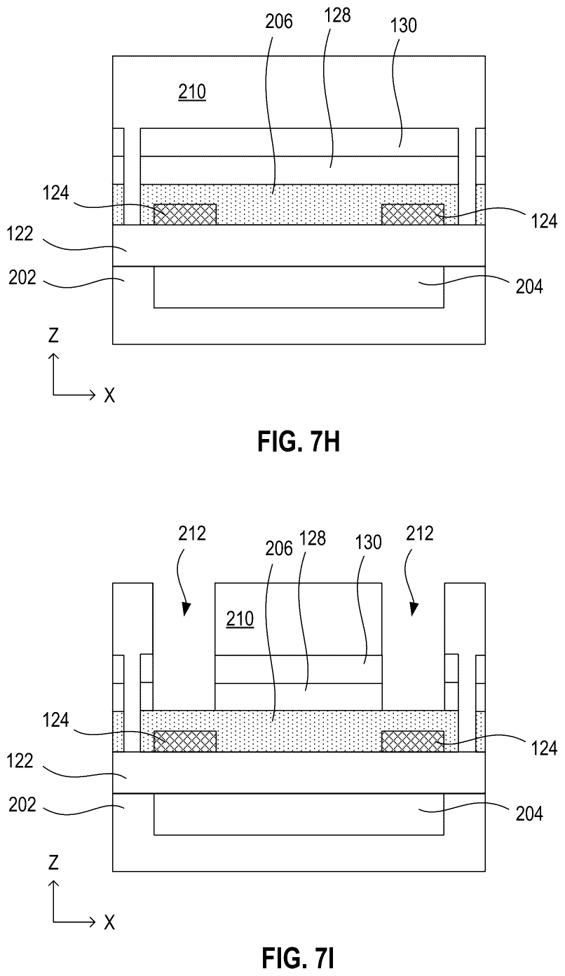

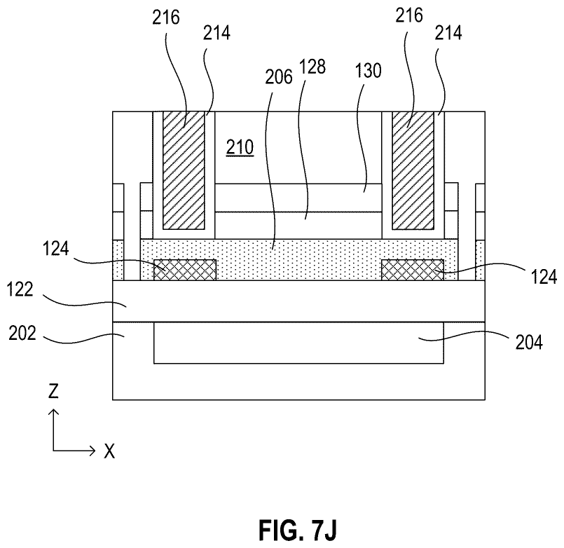

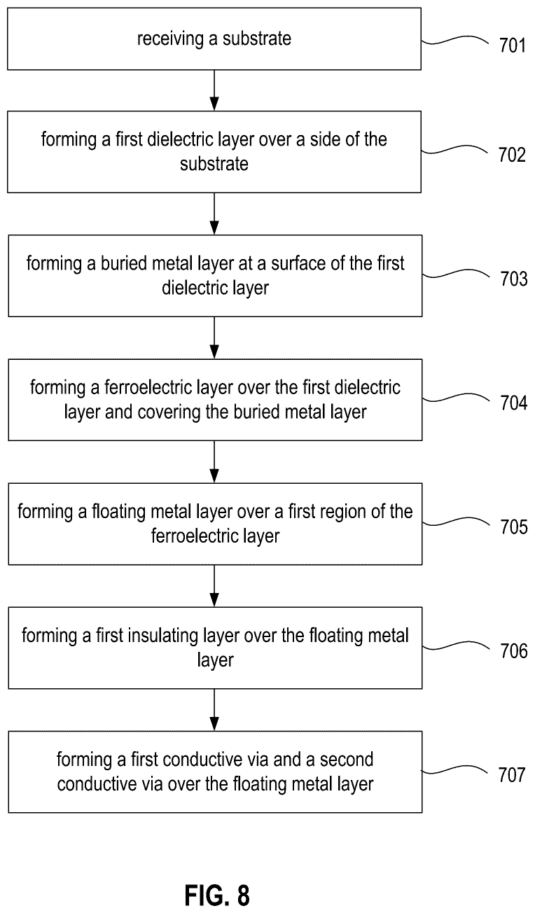

Referring to FIGS. 7A to 7J and FIG. 8, in the method for manufacturing the semiconductor structure in some embodiments of the present disclosure, the operations can include the followings. As illustrated in FIG. 7A, a substrate 100 can be received (i.e., S701: receiving a substrate). The substrate 100 may have the structures such as the FEOL structure 104 and/or the MEOL structure 106 formed therein/thereon, these structures were previously described in introducing the semiconductor structure in FIG. 1.

Next, in some embodiments, referring to FIG. 7B and FIG. 8, the formation of a metallization structure 102 over the substrate 100 can begin. For instance, a first dielectric layer 202 can be formed over a side of the substrate 100 (i.e., S702: forming a first dielectric layer over a side of the substrate). The first dielectric layer 202 a portion of one of the IMD in the metallization structure 102. In some embodiments, the material of the first dielectric layer 202 can include oxide (e.g., a silicon oxide (SiOₓ) and/or another oxide material), undoped silicate glass (USG), a boron-containing silicate glass (BSG), fluorine-containing silicate glass (FSG), tetraethyl orthosilicate (TEOS), hydrogen silsesquioxane (HSQ), and/or another suitable dielectric material. In some embodiments, the first dielectric layer 202 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

Referring to FIG. 7C and FIG. 8, in some embodiments, a buried metal layer 204 can be formed at a surface of the first dielectric layer 202 (i.e., S703: forming a buried metal layer at a surface of the first dielectric layer). In FIG. 7C and the following figures, some of the structures below the first dielectric layer 202 are omitted. The buried metal layer 204 is configured to perform as the bottom metal layer 120 previously shown in the embodiment in FIG. 2. The buried metal layer 204 can be formed through a buried metal deposition process and a chemical mechanical polishing (CMP) process. For instance, the first dielectric layer 202 can be patterned from the surface thereof, and the metal material can be deposited through the deposition technique such as CVD, PVD, ALD, or equivalent techniques. The unwanted metal material can be subsequently removed. In some embodiments, the material of the buried metal layer 204 can include tungsten (W), titanium nitride (TiN), copper (Cu), aluminum (Al), gold (Au), platinum (Pt), etc. In some embodiments, the thickness of the buried metal layer 204 is in a range from about 50 nm to about 10,000 nm.

Referring to FIG. 7D and FIG. 8, in some embodiments, the ferroelectric layer 122 is formed over the first dielectric layer 202 and covering the buried metal layer 204 (i.e., S704: forming a ferroelectric layer over the first dielectric layer and covering the buried metal layer). In some embodiments, the material of the ferroelectric layer 122 can include HfO₂, Zr-doped HfO₂, Al-doped HfO₂, PbTiO₃, SrTiO₃, etc. In some embodiments, the thickness of the ferroelectric layer 122 is in a range from about 1 nm to about 1,000 nm.

Referring to FIG. 7E and FIG. 8, in some embodiments, the floating metal layer 124 is formed over a first region 122A of the ferroelectric layer 122 (i.e., S705: forming a floating metal layer over a first region of the ferroelectric layer). In some embodiments, the floating metal layer 124 can be formed by blanket depositing the floating metal layer 124 over the ferroelectric layer 122, and then patterning the floating metal layer 124 to expose a second region 122B of the ferroelectric layer. In some embodiments, the second region 122B of the ferroelectric layer 122 surrounded by the first region 122A is free from being covered by the floating metal layer 124. In some embodiments, the floating metal layer 124 can formed by patterning the photoresist and depositing the floating metal. In some embodiments, the material of the floating metal layer 124 can include tungsten (W), titanium nitride (TiN), copper (Cu), aluminum (Al), gold (Au), platinum (Pt), etc. In some embodiments, the thickness of the floating metal layer 124 is in a range from about 0.1 nm to about 50 nm. In some embodiments, the profile of the floating metal layer 124 from the top view perspective can be a rectangular or a circular profile from the top view perspective. In other embodiments, the profile of the floating metal layer 124 can be two separated blocks from the top view perspective.

Referring to FIG. 7F and FIG. 8, in some embodiments, a first insulating layer 206 can be formed over the floating metal layer 124 (i.e., S706: forming a first insulating layer over the floating metal layer). In some embodiments, the first insulating layer 206 can be formed by blanket depositing the first insulating layer 206 over the ferroelectric layer 122. In some embodiments, a subsequent CMP process can be considered. In some embodiments, the material of the first insulating layer 206 can include SiO₂, SiNₓ, HfOₓ, AlOₓ, etc. In some embodiments, the thickness of the first insulating layer 206 is in a range from about 1 nm to about 50 nm.

Referring to FIG. 7G, in some embodiments, the channel layer 128, the cap layer 130 can be subsequently formed over the first insulating layer 206. In some embodiments, the material of the channel layer 128 can include InP, GaP, GaN, GaSb, GaAs, AlAs, InAs, InSb, AlGaAs, Si, Ge, SiGe, InGaZnO, InOₓ, GaZnOₓ, InGaSnOₓ, GaInAs, GaInP, InAlAs, InGaAs, AlInGaP SnOₓ, etc. In some embodiments, the thickness of the channel layer 128 is in a range from about 1 nm to about 500 nm. In some embodiments, the material of the cap layer 130 can include AlOₓ, or SiOₓ (x=0 to 2). In some embodiments, the thickness of the cap layer 130 is in a range from about 1 nm to about 500 nm. In some embodiments, the stack of the channel layer 128 and the cap layer 130 is patterned to form an isolation trench 208. The isolation trench 208 is formed to cut off the channel layer 128. In some embodiments, the trench 208 can be extended towards the side of the substrate 100 to penetrate the first insulating layer 206, or further penetrate the ferroelectric layer 122.

Referring to FIGS. 7H and 7I, in some embodiments, a second dielectric layer 210 is formed over the cap layer 130 and filled the trench 208. The second dielectric layer 210 will become the dielectric portion of in the metallization structure 102 (e.g., the IMD). The second dielectric layer 210 can be patterned further to form a source/drain trench 212 expose the first insulating layer 206 with in the first region 122A of the ferroelectric layer 122.

Referring to FIG. 7J and FIG. 8, in some embodiments, the source/drain trench 212 is formed to form the source/drain structure over the floating metal layer 124. In some embodiments, the first conductive via 134 and the second conductive via 136 are formed over the floating metal layer 124 (i.e., S707: forming a first conductive via and a second conductive via over the floating metal layer). In some embodiments, a conductive metal oxide layer 214 can be deposited in the source/drain trench 212 before depositing the source/drain metal 216 in the source/drain trench 212. In some embodiments, the conductive metal oxide layer 214 can include InZnO, InOₓ, InGaZnO, SnOₓ, InSnOₓ, etc. In some embodiments, the thickness of the conductive metal oxide layer 214 can in a range from about 1 nm to about 5 nm. In some embodiments, the conductive metal oxide layer 214 can be replaced by a layer including a high donor density (ND) semiconductor material.

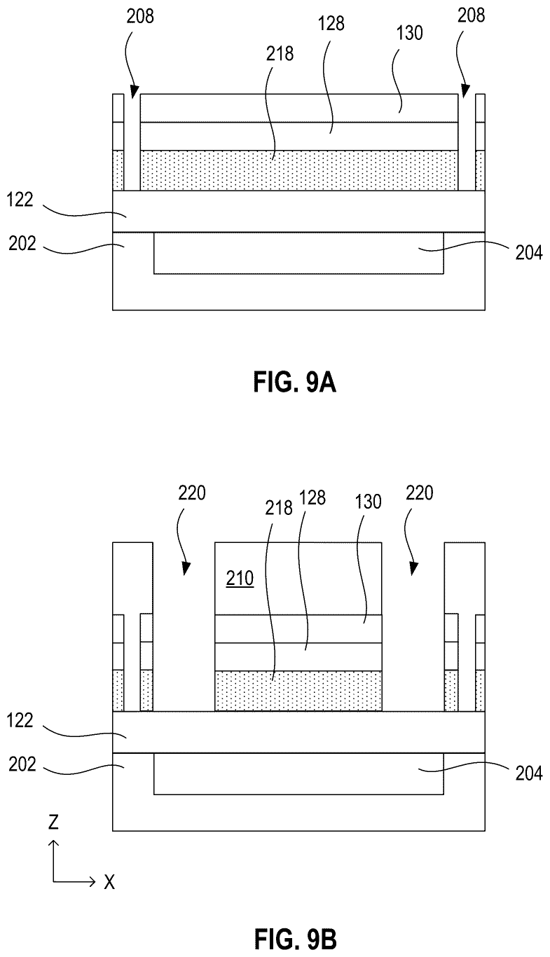

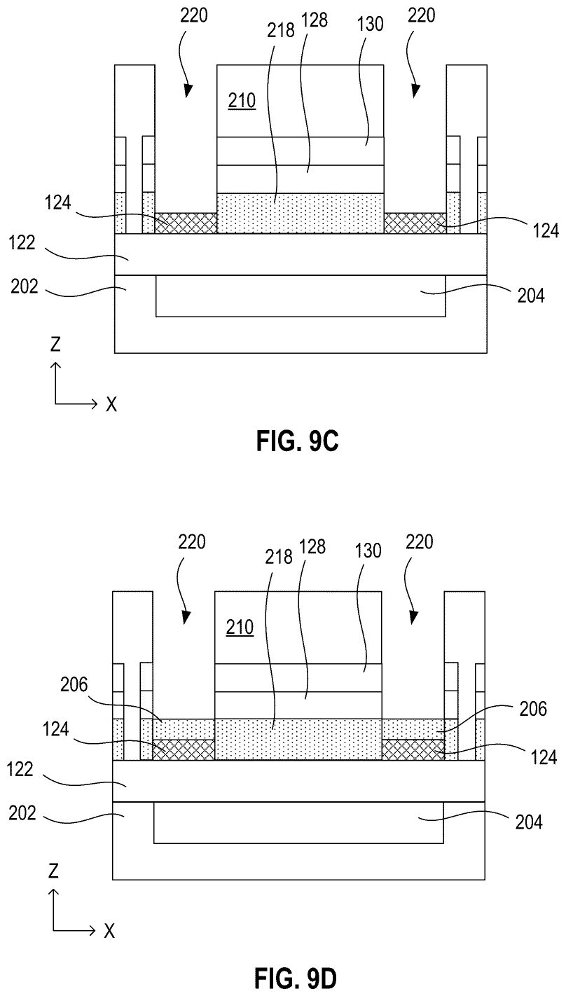

Alternatively, in other embodiment, the timing for forming the floating metal layer can be changed. Referring to FIGS. 9A to 9D, in the method for manufacturing the semiconductor structure in some embodiments of the present disclosure, the floating metal layer can be formed after the channel layer and the cap layer are formed. As illustrated in FIG. 9A, a second insulating layer 218 can be formed over the ferroelectric layer 122, and the channel layer 128 and the cap layer 130 are formed over the second insulating layer 218. In some embodiments, the isolation trench 208 penetrating the channel layer 128 and the cap layer 130 can be formed.

Referring to FIG. 9B, in some embodiments, the second dielectric layer 210 is formed over the cap layer 130 and filled the trench 208. Then, the second dielectric layer 210 can be patterned to expose the ferroelectric layer 122. In some embodiments, a trench 220 penetrating the second dielectric layer 210, the cap layer 130, the channel layer 128, and the second insulating layer 218 can be formed accordingly.

Referring to FIG. 9C, in some embodiments, the material of the floating metal layer 124 can be filled on the exposed ferroelectric layer 122 (i.e., the material of the floating metal layer are disposed on the bottom of the trench 220). The floating metal layer 124 is in contact with the ferroelectric layer 122. In some embodiments, the thickness of the floating metal layer 124 is less than the thickness of the second insulating layer 218, and therefore a top surface of the second insulating layer 218 is substantially higher than a top surface of the floating metal layer 124. In some embodiment, the floating metal layer 124 is formed by an anisotropic deposition, such as the PVD technique.

Referring to FIG. 9D, in some embodiments, the first insulating layer 206 is then disposed over the floating metal layer 124 within the trench 220. In some embodiments, the thickness of the first insulating layer 206 is less than the thickness of the second insulating layer 218. In some embodiments, the side of the first insulating layer 206 is at least in contact with the second insulating layer 218, and therefore the insulating layer, which is composed of the first insulating layer 206 and the second insulating layer 218, is substantially a continuous layer that having different thicknesses among different regions. In some embodiments, the thickness of the first insulating layer 206 and/or the thickness of the floating metal layer 124 can be varied within a certain range. Therefore, in some examples, a top surface of the first insulating layer 206 can be higher than the top surface of the second insulating layer 218, while the side of the channel layer 128 is free from entirely being covered by the first insulating layer 206. In some embodiments, the top surface of the first insulating layer 206 can be lower than the top surface of the second insulating layer 218. In other examples, the top surface of the first insulating layer 206 can be aligned with the top surface of the second insulating layer 218.

The formation of the first conductive via 134 and the second conductive via 136 in trench 220 is substantially identical to the description regarding FIG. 7J of the present disclosure and is omitted here for brevity.

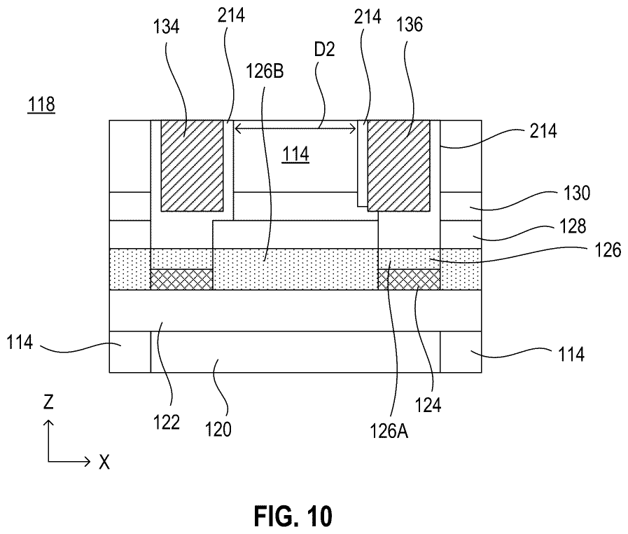

In some embodiments shown in FIG. 2, the distance D1 between the first conductive via 134 and the second conductive via 136 can in a range from about 3 nm to about 1,000 nm. Referring to FIG. 10, in some embodiment, the distance D2 between the first conductive via 134 and the second conductive via 136 can be narrower compared to the embodiments previously shown in FIG. 2. For instance, the first conductive via 134 and the second conductive via 136 may at least partially overlap with the channel layer 128 there between, and therefore a portion of the top surface of the channel layer 128 may in contact with the conductive metal oxide layer 214 (or high donor density (ND) semiconductor material in other examples). In some embodiments, a bottom of each of the first conductive via 134 and the second conductive via 136 can be higher than a top surface of the channel layer 128; in such embodiments, the thickness of the conductive metal oxide layer 214 filled under the first conductive via 134 and the second conductive via 136 can be greater than that in the embodiment shown in FIG. 2.

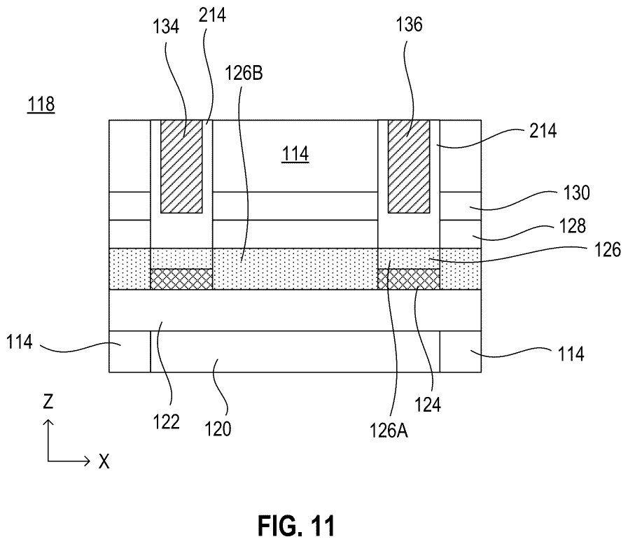

Referring to FIG. 11, in other embodiments, alternatively, the distance between the first conductive via 134 and the second conductive via 136 can be substantially identical to the embodiments previously shown in FIG. 2, whereas the thickness of the conductive metal oxide layer 214 filled under the first conductive via 134 and the second conductive via 136 can be greater than that in the embodiment shown in FIG. 2. In the embodiments shown in FIG. 11, the bottom of each of the first conductive via 134 and the second conductive via 136 can be higher than the top surface of the channel layer 128.

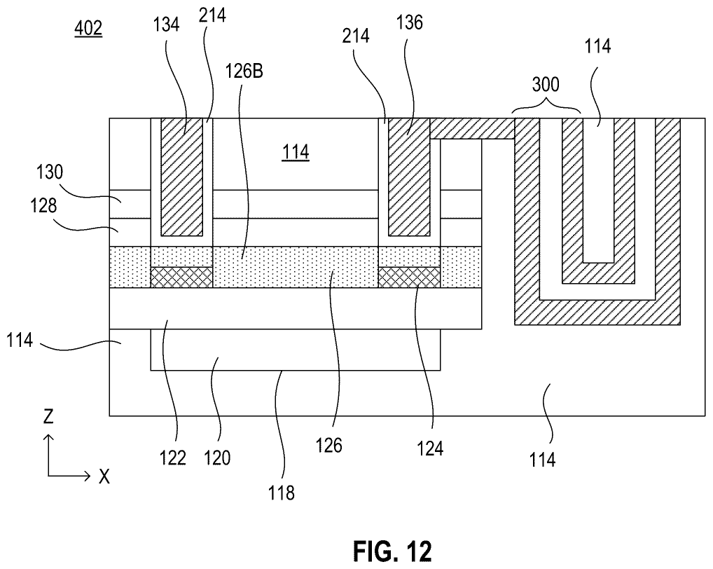

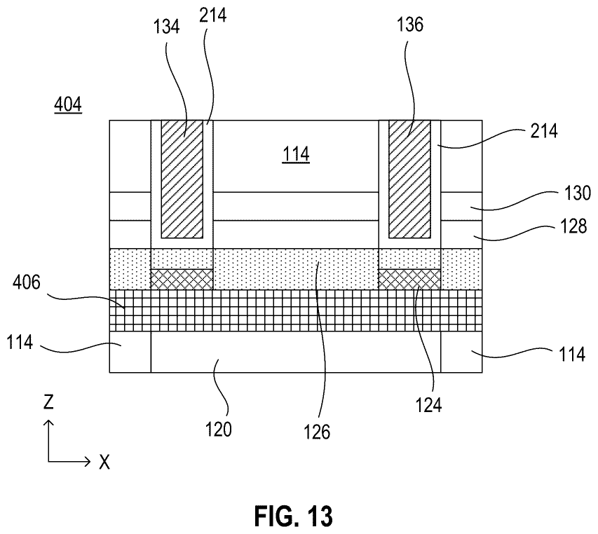

FIG. 12 illustrates an example in implementing some embodiments of the present disclosure. In such example, a 1F1C structure 402 is provided by electrically connecting the memory structure 118 to a capacitor structure 300 through a metal line connecting the conductive via in the memory structure 118 to the electrode in the capacitor structure 300. Furthermore, as shown in FIG. 13, a thin-film transistor (TFT) structure 404 can be derived from the integrated memory structure disclosed in the embodiments of the present disclosure. In the example of TFT structure 404, the ferroelectric layer illustrated in previous embodiments can be replaced by a high-k layer 406, which includes a high-k material such as SiOₓ, HfOₓ, ZrOₓ, TaOₓ, HfSiOₓ, etc.

In one exemplary aspect, a semiconductor structure is provided. The semiconductor structure includes a substrate, a metallization structure over the substrate, and a memory structure embedded in the metallization structure. The metallization structure includes at least a dielectric layer and at least a conductive line layer. The memory structure is further laterally surrounded by the dielectric layer. The memory structure includes a bottom metal layer, a ferroelectric layer, a floating metal layer, and an insulating layer. The ferroelectric layer is over the bottom metal layer. The floating metal layer is over the ferroelectric layer. The insulating layer is over the floating metal layer. The metallization structure further includes a first conductive via and a second conductive via over the insulating layer and in proximity to two opposite sides of the floating metal layer, respectively.

In another exemplary aspect, a semiconductor structure is provided. The semiconductor structure includes a metallization structure and a memory structure embedded in the metallization structure. The metallization structure includes a dielectric layer and at least a conductive line layer. The memory structure further laterally surrounded by the dielectric layer. The memory structure includes a bottom metal layer, a ferroelectric layer, a floating metal layer, and an insulating layer. The ferroelectric layer is over the bottom metal layer. The ferroelectric layer has a first region, and a second region surrounded by the first region from a cross-sectional view perspective. The floating metal layer is over the first region of the ferroelectric layer. The insulating layer is over the floating metal layer and the ferroelectric layer. The metallization structure further includes a first conductive via and a second conductive via over the insulating layer and projectively over the floating metal layer.

In yet another exemplary aspect, a method for manufacturing a semiconductor structure is provided. The method includes the operations as follows. A first dielectric layer is formed over a side of the substrate. A buried metal layer is formed at a surface of the first dielectric layer; A ferroelectric layer is formed over the first dielectric layer and covering the buried metal layer. A floating metal layer is formed over a first region of the ferroelectric layer, wherein a second region of the ferroelectric layer surrounded by the first region from a cross-sectional view perspective is free from being covered by the floating metal layer. A first insulating layer is formed over the floating metal layer. A first conductive via and a second conductive via are formed over the floating metal layer.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a metallization structure over the substrate, comprising at least a dielectric layer and at least a conductive line layer; and
a memory structure embedded in the metallization structure and laterally surrounded by the dielectric layer, the memory structure comprises:
a bottom metal layer;
a ferroelectric layer over the bottom metal layer;
a floating metal layer over the ferroelectric layer; and
an insulating layer over the floating metal layer,
wherein the metallization structure further comprises a first conductive via and a second conductive via over the insulating layer and in proximity to two opposite sides of the floating metal layer, respectively.

2. The semiconductor structure of claim 1, wherein a side of the ferroelectric layer is aligned to a side of the insulating layer, and the side of the ferroelectric layer is free from aligning to a side of the bottom metal layer.

3. The semiconductor structure of claim 1, wherein the floating metal layer is covered by a first portion of the insulating layer and laterally surrounded by a second portion of the insulating layer.

4. The semiconductor structure of claim 3, wherein a thickness of the floating metal layer is less than a thickness of the second portion of the insulating layer.

5. The semiconductor structure of claim 1, wherein the floating metal layer comprises a ring profile from a top view perspective.

6. The semiconductor structure of claim 1, wherein the floating metal layer comprises a first portion and a second portion isolated from the first portion.

7. The semiconductor structure of claim 1, wherein the two opposite sides of the floating metal layer are substantially aligned to two opposite sides of the bottom metal layer.

8. The semiconductor structure of claim 1, wherein the memory structure further comprises:
a channel layer over the insulating layer; and
a cap layer over the channel layer.

9. The semiconductor structure of claim 1, wherein a height of the memory structure is less than a thickness of the dielectric layer in the metallization structure.

10. A semiconductor structure, comprising:
a metallization structure comprising at least a dielectric layer and at least a conductive line layer; and
a memory structure embedded in the metallization structure and laterally surrounded by the dielectric layer, the memory structure comprises:
a bottom metal layer;
a ferroelectric layer over the bottom metal layer, wherein the ferroelectric layer has a first region and a second region surrounded by the first region from a cross-sectional view perspective;
a floating metal layer over the first region of the ferroelectric layer; and
an insulating layer over the floating metal layer and the ferroelectric layer,
wherein the metallization structure further comprises a first conductive via and a second conductive via over the insulating layer and projectively over the floating metal layer.

11. The semiconductor structure of claim 10, wherein the floating metal layer comprises a ring profile from a top view perspective.

12. The semiconductor structure of claim 10, wherein the floating metal layer comprises two portions separated from each other from a top view perspective.

13. The semiconductor structure of claim 10, wherein the insulating layer is in contact with the ferroelectric layer within the second region of the ferroelectric layer.

14. The semiconductor structure of claim 10, wherein a thickness of the insulating layer over the first region of the ferroelectric layer is substantially different from a thickness of the insulating layer over the second region of the ferroelectric layer.

15. A method for manufacturing a semiconductor structure, the method comprising:
receiving a substrate;
forming a first dielectric layer over a side of the substrate;
forming a buried metal layer at a surface of the first dielectric layer;
forming a ferroelectric layer over the first dielectric layer and covering the buried metal layer;
forming a floating metal layer over a first region of the ferroelectric layer, wherein a second region of the ferroelectric layer surrounded by the first region is free from being covered by the floating metal layer;
forming a first insulating layer over the floating metal layer; and
forming a first conductive via and a second conductive via over the floating metal layer.

16. The method of claim 15, further comprising:
forming a second insulating layer over the ferroelectric layer prior to forming the floating metal layer;
patterning the first insulating layer to expose the first region of the ferroelectric layer; and
forming the floating metal layer over the first region of the ferroelectric layer by filling a floating metal material in contact with the ferroelectric layer.

17. The method of claim 16, wherein a thickness of the second insulating layer is greater than a thickness of the first insulating layer.

18. The method of claim 16, prior to patterning the first insulating layer, further comprising:
forming a channel layer over the second insulating layer;
forming a cap layer over the channel layer; and
patterning the channel layer and the cap layer to form an isolation trench, wherein the buried metal layer is projectively enclosed by the isolation trench.

19. The method of claim 18, wherein a bottom of the isolation trench is lower than a bottom of the buried metal layer from a cross-sectional view perspective.

20. The method of claim 15, further comprising:
blanket depositing the floating metal layer over the ferroelectric layer;
patterning the floating metal layer to expose the second region of the ferroelectric layer; and
forming the first insulating layer by blanket depositing the first insulating layer over the ferroelectric layer.
